(19) United States
(12) Patent Application Publication
(10) Pub. No.: US 2008/0001668 A1
(43) Pub. Date: Jan. 3, 2008

(54) IMPEDANCE CONTROL DEVICE AND IMPEDANCE CONTROL METHOD

(75) Inventor: Takuro TSUJIGAWA, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION, Kanagawa (JP)

(21) Appl. No.: 11/761,065

(22) Filed: Jun. 11, 2007

(30) Foreign Application Priority Data
Jun. 14, 2006 (JP) 2006-164191

(51) Int. Cl. H03F 3/26

(52) U.S. Cl. 330/267

(57) ABSTRACT

A compact semiconductor device for controlling impedance is provided. The semiconductor device has: a replica transistor of a transistor included in a control target circuit; and a substrate bias control circuit for controlling the impedance of the control target circuit by applying a substrate bias potential to the transistor in the control target circuit. The substrate bias potential is fed back to the substrate bias control circuit via the replica transistor.

### BACKGROUND OF THE INVENTION

1. Field of the Invention

The present invention relates to a semiconductor device, particularly an impedance control circuit and an impedance control method in which the input impedance or output impedance of a controlled object circuit is controlled to a desired value.

2. Description of Related Art

In recent years, impedance matching between a semiconductor device and a transmission path has become increasingly important in a field of a high-speed interface represented by the SerDes (Serializer/Deserializer) in accordance with implementation of high-speed operations of semiconductor devices. In an I/O interface connected to the transmission path, impedance mismatching with a transmission path is occurred due to impedance fluctuation caused by a manufacturing deviations or temperature dependency of elements such as a transistor and resistor disposed in a terminal of the interface and fluctuation of a power supply voltage or the like.

In order to solve the above described problems, an impedance control circuit can be used. The impedance control circuit references a high accuracy external resistor to match the impedance of a driver or the input impedance of a receiver to the resistance of the external resistor. An example of impedance control circuits is described in Japanese Laid-Open Patent Application (JP-A-Heisei, 11-177380), and Japanese Laid-Open Patent Application (JP-P2005-026890A).

In each of these documents, an impedance control circuit described controls the impedance of a circuit which is the object of the impedance control (ex. driver circuit) having a pull-up circuit and a pull-down circuit. In JP-A-Heisei, 11-177380, the impedance control circuit controls respective impedance of the pull-up circuit and the pull-down circuit independently, so that a more accurate impedance control is realized. Moreover, in JP-P2005-026890A, a MOS array circuit corresponding to a pull-up circuit and a pull-down circuit respectively is used to simulate the operation of a driver circuit, so that the impedance of the driver circuit is controlled in accordance with majority logic of the simulation result.

The configuration and operation of an example of impedance control circuits is explained below. FIG. 1 shows the configuration of an impedance control circuit 200 and a driver circuit 110 being an object of the impedance control. The driver circuit 110 is provided with a pull-up circuit 61 having a plurality of P-channel-type MOS transistors (each of them is referred to as PMOS hereinafter), and a pull-down circuit 62 having a plurality of N-channel-type MOS transistors (referred to NMOS). The impedance control circuit 200 is provided with a PMOS array 63 as a replica circuit having the same configuration with the pull-up circuit 61, and an NMOS array 67 as a replica circuit having the same configuration with the pull-down circuit 62. It is also provided with comparators 65 and 69 and up-down counters 66 and 69 that correspond to the pull-up circuit 61 and the pull-down circuit 62 respectively.

Each drain of the PMOSs in the PMOS array 63 is connected to an external resistor 80 via a connection terminal 64. The connection terminal 64 is also connected to an inverted input terminal of the comparator 65, so that a divided voltage V_{C1} provided by the external resistor 80 and the PMOS array 63 is supplied to the comparator 65. Similarly, each drain of the NMOSs in the NMOS array 67 is connected to an external resistor 90 via a connection terminal 68. The connection terminal 68 is also connected to a non-inverted input terminal of the comparator 69, so that a divided voltage V_{C2} provided by the external resistor 90 and the NMOS array 67 is supplied to the comparator

The comparator 65 compares the divided voltage V_{C1} with a reference voltage V_{ref} inputted to the non-inverted input terminal thereof to output a comparison result to the up-down counter 66. The up-down counter 66 outputs a count value (binary value) corresponding to the comparison result to the pull-up circuit 61 and each gate of the PMOSs in the PMOS array 63. In the pull-up circuit 61 and the PMOS array 63, a stage number of the PMOSs driven in accordance with the count value is determined. Similarly, the comparator 69 compares the divided voltage V_{C2} with the reference voltage V_{ref} inputted to an inverted input terminal to output a comparison result to the up-down counter 70. The up-down counter 70 outputs a count value (binary value) corresponding to the comparison result to the pull-down circuit 62 and each gate of the NMOSs in the NMOS array 67. In the pull-down circuit 62 and the NMOS array 67, a stage number of the NMOSs driven in accordance with the count value is determined.

The value of the divided voltages V_{C1} and V_{C2} determined by the stage number of the PMOS and NMOS to be driven is subjected to feedback to the comparators 63 and 69. The operation as described above is repeated, and if the voltage difference between the divided voltages V_{C1} and V_{C2} and the reference voltage V_{ref} is made to be equal to or less than a preset value, the output impedance Zₒᵤₜ in a connection point 60 between the pull-up circuit 61 and the pull-down circuit 62 is controlled to a desired value.

### SUMMARY

As described above, the impedance control circuit 200 determines driven transistors by a digital signal obtained from a counter to control the output impedance.

The present inventor has recognized that in the case of the configuration as described above, a circuit being an object of an impedance control (ex. driver circuit) needs to have a plurality of transistors. It is the same in the impedance control circuit described in the above mentioned patent documents.

In one embodiment of the present invention, a semiconductor device includes: a first replica transistor being a replica of a first transistor included in a control target circuit; and a first substrate bias control circuit configured to control an impedance of the control target circuit by applying a first substrate bias potential to a substrate of the first transistor, the first substrate bias potential being fed back to the first substrate bias control circuit via the first replica transistor.

By including such configuration, the present invention can provide a semiconductor device and an impedance control method, which allow a reduction of a circuit area. From another viewpoint, a reduction of manufacturing costs can be realized. From further another viewpoint, it is possible to control input impedance and output impedance of the semiconductor device to a desired value in a short period of time.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a diagram showing a configuration of an impedance control circuit in a related art;

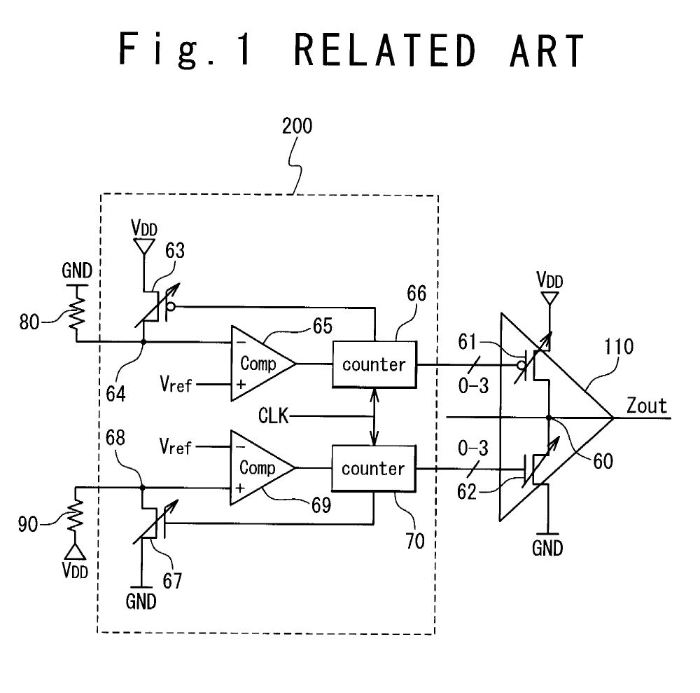

FIG. 2 is a block diagram showing a configuration in an embodiment of a semiconductor device according to the present invention;

FIG. 3 is a block diagram showing a configuration in a first embodiment of the substrate bias control circuit according to the present invention;

FIG. 4 is a timing chart showing an impedance control operation in an embodiment of the semiconductor device according to the present invention; and

FIG. 5 is a block diagram showing a configuration in a second embodiment of the substrate bias control circuit according to the present invention.

### DETAILED DESCRIPTION OF PREFERRED EMBODIMENTS

The invention will be now described herein with reference to illustrative embodiments. Those skilled in the art will recognize that many alternative embodiments can be accomplished using the teaching of the present invention and that the invention is not limited to the embodiments illustrated for explanatory purposes.

In the drawings, an identical or similar reference number indicates that the corresponding configuration elements are identical, similar, or equivalent to each other. Redundant explanation will be omitted in identical or similar configuration elements. The embodiments will be explained in a case of an impedance control circuit which controls output impedance of a driver circuit.

### 1. General Configuration

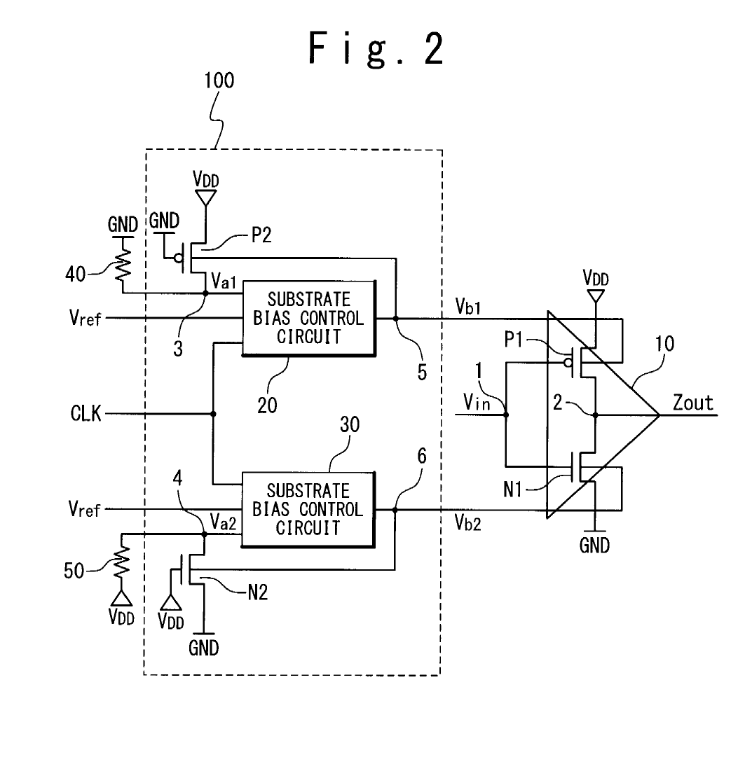

Referring now to FIG. 2, a general configuration of the circuit of the semiconductor device according to embodiments of the present invention is shown. The semiconductor device includes a driver circuit 10 and an impedance control circuit 100 that are mounted on a same IC chip. The driver circuit 10 outputs an output signal Vᵢₙ which is outputted from an internal circuit (not shown) formed on the same IC chip, to an external transmission path. The impedance control circuit 100 controls output impedance of the driver circuit 10 referring to highly accurate external resistors 40 and 50 disposed outside of the IC chip, so that output impedance Zₒᵤₜ is matched between the transmission path (not shown) and the driver circuit 10.

Referring to FIG. 2, the driver circuit 10 is provided with a P-channel-type MOS transistor P1 (referred to as a transistor P1 hereinafter) which is connected to a first power supply providing a constant potential V_{DD} (referred to as a power supply V_{DD} hereinafter) and forms a pull-up circuit, and an N-channel-type MOS transistor N1 (referred to as a transistor N1 hereinafter) which is connected to a second power supply providing a ground potential GND (referred to as a power supply GND hereinafter) and forms a pull-down circuit. That is, a CMOS is formed by the transistor P1 and the transistor N1. The output signal Vᵢₙ is inputted to each gate of the transistors P1 and N1 via an input terminal 1, so that a signal based on the output signal Vᵢₙ is outputted to the external transmission path via an output terminal 2. Substrate bias voltages V_{b1} and V_{b2} are also supplied to each substrate of the transistors P1 and N1 via bias supply terminals 5 and 6 respectively.

The impedance control circuit 100 is provided with a transistor P2 which is a replica circuit of the transistor P1, and a transistor N2 which is a replica circuit of the transistor N1. It is also provided with a substrate bias control circuit 20 which supplies a substrate bias voltage V_{b1} to the transistors P1 and P2, and a substrate bias control circuit 30 which supplies a substrate bias voltage V_{b2} to the transistors N1 and N2.

The gate of the transistor P2 is connected to the power supply GND, the source thereof is connected to the power supply V_{DD}, and the drain thereof is connected to one end of the external resistor 40 via a connection terminal 3. The other end of the external resistor 40 is also connected the power supply GND. That is, the connection terminal 3 is pulled up by the transistor P2, and pulled down by the external resistor 40. Therefore, a divided voltage Vₐ₁ made by the external resistor 40 and the transistor P2 is supplied to the substrate bias control circuit 20. Similarly, the gate of the transistor N2 is connected to the power supply V_{DD}, the source thereof is connected to the power supply GND, and the drain thereof is connected to one end of the external resistor 50 via a connection terminal 4. The other end of the external resistor 50 is also connected to the power supply V_{DD}. That is, the connection terminal 4 is pulled down by the transistor N2, and pulled up by the external resistor 50. Therefore, a divided voltage Vₐ₂ made by the external resistor 50 and the transistor N2 is supplied to the substrate bias control circuit 30 via the connection terminal 4.

The substrate bias control circuits 20 and 30 compare the inputted divided voltages Vₐ₁ and Vₐ₂ with a reference voltage V_{ref} respectively to output the result as the substrate bias voltages V_{b1} and V_{b2}. The substrate bias voltage V_{b1} is supplied to the transistors P1 and P2 via the bias supply terminal 5, and V_{b2} is supplied to the transistors N1 and N2 via the bias supply terminals 6. The reference voltage V_{ref} here is generated by a reference voltage generating circuit (ex. highly accurate dividing resistor) not shown, and set in accordance with a desired value of the output impedance Zₒᵤₜ. That is, the reference voltage V_{ref} is set to be a voltage value at the connection terminals 3 and 4 when impedances are matched between the output terminal 2 and the transmission path.

Due to the configuration as described above, the substrate bias voltages V_{b1} and V_{b2} are subjected to feedback to the substrate bias control circuits 20 and 30 as the divided voltages Vₐ₁ and Vₐ₂ via the transistors P2 and N2 that are replica circuits of the driver circuit 10, so that the output impedance Zₒᵤₜ in the driver circuit 10 is controlled to a desired value.

### 2. First Embodiment

### (Configuration of the Substrate Bias Control Circuits 20 and 30)

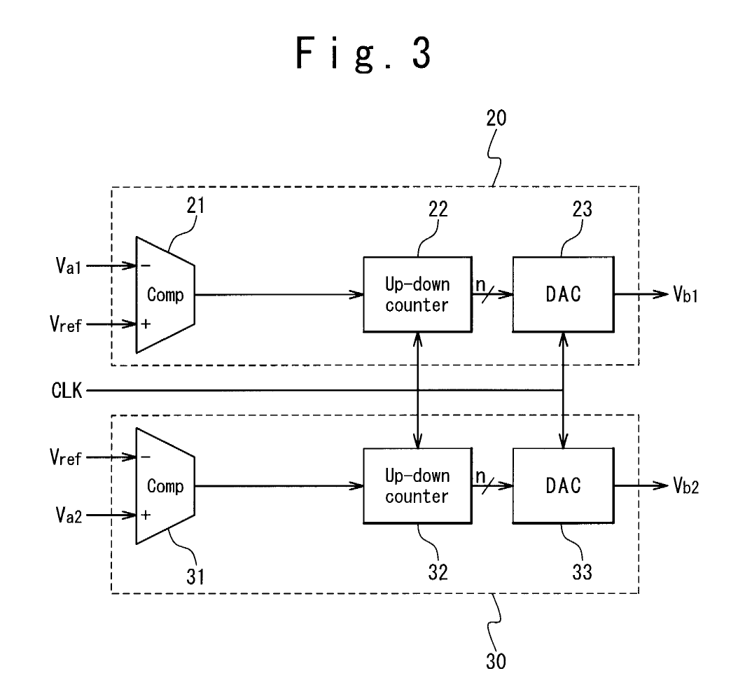

FIG. 3 is a block diagram showing the configuration in first embodiment of the substrate bias control circuits 20 and 30 according to the present invention. Referring to FIG. 3, the configuration in the first embodiment of the substrate bias control circuits 20 and 30 is explained. The substrate bias control circuit 20 in this embodiment is provided with a comparator 21, an up-down counter (referred to as a counter hereinafter) 22, and a D/A converter (referred to as a DAC hereinafter) 23. The divided voltage Vₐ₁ is supplied to the inverted input terminal of the comparator 21, and the reference voltage V_{ref} is supplied to the non-inverted input terminal thereof. The comparator 21 outputs the result of comparison between the divided voltage Vₐ₁ and the reference voltage V_{ref} to the counter 22. The counter 22 counts up or counts down a counter value (binary value) on the basis of the comparison result. The DAC 23 applies D/A conversion to the counter value inputted from the counter 22 so as to output the substrate bias voltage V_{b1} being an analog value to the bias supply terminal 5.

Similarly, the substrate control circuit 30 is provided with a comparator 31, an up-down counter (referred to as a counter hereinafter) 32, a D/A converter (referred to as a DAC hereinafter) 33. The divided voltage Vₐ₂ is supplied to the non-inverted input terminal of the comparator 31, and the reference voltage V_{ref} is supplied to the inverted input terminal thereof. The comparator 31 outputs the result of comparison between the divided voltage Vₐ₁ and the reference voltage V_{ref} to the counter 32. The counter 32 counts up or counts down a count value (binary value) on the basis of the comparison result. The DAC 23 applies D/A conversion to the counter value inputted from the counter 32 so as to output the bias voltage V_{b2} being an analogue value to the bias supply terminal 6. Since the substrate bias controls circuits 20 and 30 are configured in the similar manner, a configuration of the substrate bias control circuit 20 will be representatively explained below in details.

The comparator 21 compares the divided voltage Vₐ₁ with the reference voltage V_{ref}, so as to output a low level signal if the divided voltage Vₐ₁ is larger than the reference voltage V_{ref}, and output a high level signal if the divided voltage Vₐ₁ is smaller than the reference voltage V_{ref}.

The counter 22 is an n-bit binary counter which obtains a comparison result outputted from the comparator 21 by synchronizing to a clock signal CLK and determines a count value by corresponding to the obtained value of the comparison result. The counter 22 obtains the comparison result in response to a rising edge of the clock signal CLK, in which the count value is counted up by one in the case of having a high level signal in a comparison result, and is counted down by one in the case of having a low level signal in the comparison result.

The DAC 23 obtains the count value (binary value) from the counter 22 at every predetermined time, and applies D/A conversion thereto in order to output the substrate bias voltage V_{b1}. For example, the DAC 23 obtains the count value from the counter 22 in response to a rising edge of the clock signal CLK. The DAC 23 may also obtain the count value which has been counted for a plural number of times. In this case, the interval to obtain a count value by the DAC 23 is set to be longer than the interval to obtain a comparison result by the counter 22. That is, the counter 22 may count the comparison result by synchronizing to a clock signal which has a shorter interval than the clock signal CLK. The setting as described above allows a more appropriate output of the reference bias voltage V_{b1} when the divided voltage Vₐ₁ fluctuates across the reference voltage Vₐ₁ for a plural number of times in a short period of time within one interval of the clock signal CLK.

### (Operation)

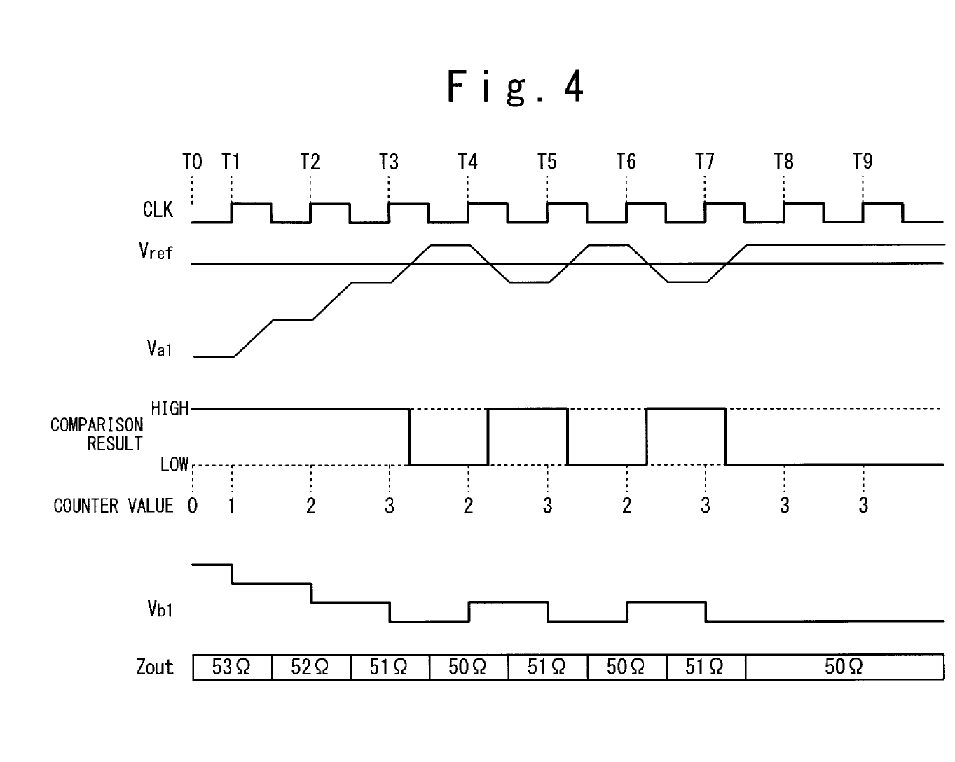

Next, the impedance control operation of the semiconductor device according to this embodiment will be explained in detail referring to FIG. 4. FIG. 4 is a timing chart in an impedance control operation in the first embodiment of the semiconductor device according to the present invention. An impedance control operation will be explained below using an example of the impedance control in which the output impedance Zₒᵤₜ of the driver circuit 10 is matched to the input impedance (supposed to be 50Ω) of the transmission path. Moreover, since the substrate bias control circuits 20 and 30 are operated in the similar manner, an operation of the substrate bias control circuit 20 will be representatively explained in detail.

Referring to FIG. 4, it is assumed that the output impedance Zₒᵤₜ in the output terminal 2 exhibits 53Ω and the count value in the counter 22 exhibits 0 initially at time T0.

At time T1, in response to a rising edge of the clock signal CLK, the counter 22 gets a high level signal as a comparison result, and counts up the count value from 0 to 1. The DAC 23 outputs the substrate bias voltage V_{b1} which is reduced by corresponding to the count value of 1. The transistors P1 and P2 reduce potential of the output terminal 2 and the divided voltage Vₐ₁ in the connection terminal 3 in response to the reduced substrate bias voltage V_{b1}. In accordance with the reduction of the substrate bias voltage V_{b1} the impedance Zₒᵤₜ in the output terminal 2 is decreased from 53Ω to 52Ω in a period from time T1 to time T2.

At time T2, the counter 22 similarly gets a high level signal as a comparison result, and counts up the count value to 2. The DAC 23 outputs the substrate bias voltage V_{b1} which is further reduced in response to the count value of 2. The transistors P1 and P2 increase potential of the output terminal 2 and the divided voltage Vₐ₁ in the connection terminal 3 in response to the decreased substrate bias voltage V_{b1}. Accordingly, the output impedance Zₒᵤₜ in the output terminal 2 is decreased from 52Ω to 51Ω. At time T3, the substrate bias voltage V_{b1} is similarly reduced, and the output impedance Zₒᵤₜ in the output terminal 2 is decreased from 51Ω to 50Ω. Moreover, in a period from time T3 to time T4, the divided voltage Vₐ₁ is increased to exceed the reference voltage V_{ref}.

At time T4, the counter 22 gets a low level signal as a comparison result, and counts down the count value from 3 to 2. The DAC 23 outputs the substrate bias voltage V_{b1} which is increased by corresponding to the count value of 2. The transistor P2 reduces the divided voltage Vₐ₁ in the connection terminal 3 in response to the increased substrate bias voltage V_{b1}. Accordingly, in a period from time T4 to T5, the output impedance Zₒᵤₜ in the output terminal 2 is increased from 50Ω to 51Ω. Moreover, in a period from time T4 to time T5, the divided voltage Vₐ₁ is decreased to fall under the reference voltage V_{ref}.

From time T5 to time T7, the operation from time T3 to time T4 is repeated and the output impedance Zₒᵤₜ fluctuates between 50Ω and 51Ω alternately. At this time, the counter 22 repeats to count up and count down alternately. The DAC 23 in the present embodiment is established to fix the output signal when the input signal repeats up and down for a predetermined number of times (count values of 3 and 2 here). Three times is employed here as a fixed value in response to signals repeated for three times.

At time T7 and thereafter, the DAC 23 outputs the substrate bias voltage V_{b1} which corresponds to a count value of 3. Therefore, the output impedance Zₒᵤₜ is fixed to 50Ω. In practice, an operation similar to the above described operation is also performed in the substrate bias control circuit 30, and the output impedance Zₒᵤₜ is determined by controlling the substrate bias voltages V_{b1} and V_{b2}. However, the direction of increasing/decreasing the divided voltage Vₐ₂ and the output impedance Zₒᵤₜ brought about by the change of the substrate bias voltage V_{b2} is opposite to the direction of increasing/decreasing the divided voltage Vₐ₁ and the output impedance Zₒᵤₜ by the substrate bias V_{b1}.

### 3. Second Embodiment

### (Configuration of the Substrate Bias Control Circuits 20 and 30)

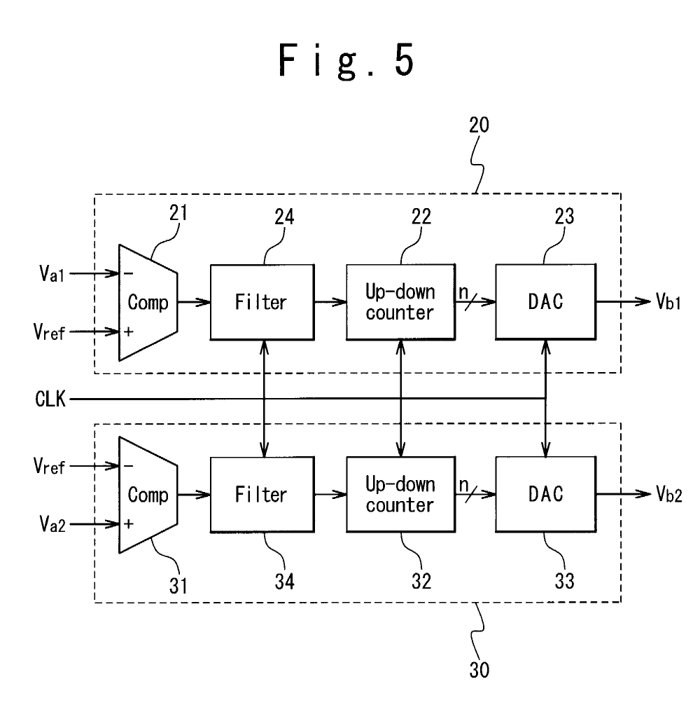

FIG. 5 is a block diagram showing the configuration in second embodiment of the substrate bias control circuits 20 and 30 according to the present invention. Referring to FIG. 5, the second embodiment of the substrate bias control circuits 20 and 30 is explained below. The substrate bias control circuit 20 in the present embodiment is configured to further include a filter 24 in addition to the substrate bias control circuit 20 in the first embodiment. The filter 24 is interposed between the comparator 21 and the counter 22, and extracts an appropriate value as a comparison result from the comparison result outputted from the comparator 21 in order to output to the counter 22. The counter 22 counts up or counts down the count value on the basis of a value (which is a filtered comparison result) inputted from the filter 24. The DAC 23 applies D/A conversion to the count value obtained from the counter 22 in order to output as the substrate bias voltage V_{b1} being an analog value to the bias supply terminal 5.

Similarly, the substrate bias control circuit 30 is configured to further include a filter 34 in addition to the substrate bias control circuit 30 in the first embodiment. The filter 34 is interposed between the comparator 31 and the counter 32, and extracts an appropriate value as a comparison result from the comparison result outputted from the comparator 31 in order to output to the counter 32. The counter 32 counts up or counts down a count value on the basis of the value (which is a filtered comparison result) inputted from the filter 34. The DAC 33 applies D/A conversion to the counter value obtained from the counter 32 in order to output as the substrate bias voltage V_{b2} being an analog value to the bias supply terminal 6.

The filter 24 here is preferably a majority filter which outputs majority value to be determined from a predetermined number of comparison results outputted from the comparator, or an average filter which outputs an average value to be determined from the predetermined number of the comparison results. In this case, a predetermined number of clock signals with phases shifted to each other (not shown) are inputted to the filter 24. The filter 24 latches the predetermined number of comparison results by synchronizing to these clock signals, so as to extract a value to be determined by the majority logic or to be the average value obtained from the predetermined number of latched comparison results. The filter 24 thus determines the output by extracting majority from comparison results or averaging comparison results in the comparator 21, so that fluctuations of a comparison result inputted to the counter 22 can be suppressed. Therefore, the substrate bias control circuit 20 is capable of suppressing the convergence time of the substrate bias voltage V_{b1}. That is, the output impedance Zₒᵤₜ in the driver circuit 10 can be made to converge to a desired value (input impedance of 50Ω in the transmission path in the present example) in a short period of time.

The impedance control operation in this embodiment has a difference in the filtering of a comparison result operated by the filters 24 and 34, and the other operations are the same with those of the first embodiment, so that the explanation thereof is omitted. The filter 24 may also be interposed between the counter 22 and the DAC 23. In this case, a majority logic result or an average value obtained from n-bit counter values outputted from the counters 22 and 24 is outputted by the filters 24 and 34 to the DACs 23 and 33.

As described above, in the semiconductor device according to the embodiments of the present invention, a circuit being a control target of an output impedance control can be configured simply by a pair of CMOS, and the replica circuit for controlling impedance can also be configured simply by two transistors corresponding to the CMOS. Therefore, significant decrease of a circuit area can be realized in comparison with impedance control circuits and a control target circuits having MOS array structure like the related arts described before. Moreover, due to the small number of configuration elements, a rate of defects caused by manufacturing deviations can be reduced in each product.

Although a semiconductor device to control output impedance of the driver circuit 10 being a target of an impedance control is used as an example in the present embodiments, the present invention can be applied to control input impedance in a receiver circuit or the like, as needles to say.

It is apparent that the present invention is not limited to the above embodiments, but may be modified and changed without departing from the scope and spirit of the invention.

Conclusively, according to embodiments of the present invention, a semiconductor device includes: a first replica transistor P2 being a replica of a first transistor P1 included in a control target circuit 10; and a first substrate bias control circuit 20 configured to control an impedance of the control target circuit 10 by applying a first substrate bias potential Vb1 to a substrate of the first transistor P1, the first substrate bias potential Vb1 being fed back to the first substrate bias control circuit 20 via the first replica transistor P2. In the semiconductor device, the substrate bias potential of the first transistor P1 is controlled based on the bias potential Vb1 to match the input or output between the device and an outer device (e.g. transmission path).

It is preferable that the first replica transistor P2 determines a first potential Val based on the first substrate bias potential Vb1. The first substrate bias control circuit 20 outputs the first substrate bias potential Vb1 based on a comparison between the first potential Val and a reference potential Vref. The first potential Val is generated by dividing a first preset voltage by a first external resistor 40 and the first replica transistor P2. The first substrate bias control circuit 20 controls the first substrate bias potential Vb1 to the first potential Va1 to converge to the reference potential Vref. Consequently, it is possible to control an impedance of the control target circuit 10 to become a desired value defined by the resistance of the first external resistor 40 and the reference potential Vref.

According to an embodiment of the present invention, the first substrate bias control circuit 20 includes: a first comparator 21, a first up-down counter 22 and a first converter 23. The first comparator 21 generates a first comparison result by comparing the first potential Val and the reference potential Vref. The first up-down counter 22 outputs a first count value based on the first comparison result. The first converter converts the first count value to an analogue value to output as the first substrate bias potential Vb1.

According to another embodiment of the present invention, the first substrate bias control circuit 20 includes a first majority filter 24. The first majority filter 24 generates a majority value by performing a majority operation to the plurality of first comparison results. The majority value is output to the first converter 23 as the first count value. Alternatively, the first substrate bias control circuit 20 includes a first averaging filter. The first averaging filter generates a first average value by averaging the plurality of first comparison results. The first count value is output to the first converter 23 as the first average value.

Preferably, in the above mentioned one or another embodiment, the control target circuit 10 further includes a second transistor N1 connected to the first transistor P1 via an output terminal. The first transistor P1 and the second transistor N1 form a complementary metal oxide semiconductor circuit. The semiconductor device of the embodiment further includes: a second replica transistor N2 being a replica of the second transistor N1; and a second substrate bias control circuit 30 configured to control the impedance of the control target circuit 10 by supplying a second substrate bias potential Vb2 to the second transistor N1, the second substrate bias potential Vb2 being fed back to the second substrate bias control circuit 30 via the second replica transistor N2. According to the semiconductor device of the embodiments, the substrate bias potentials of the first transistor P1 and the second transistor N1 which constitute a CMOS are controlled by applying the first substrate bias potential Vb1 and the second substrate bias potential Vb2 so that the matching of the input or output impedance between the control target circuit 10 and an external device (e.g. transmission path) can be achieved.

In the above explanation, reference numbers which are shown in the drawings are attached to the words which respectively indicate elements of embodiments. But the scope of the present invention should not be limited based on the correspondence relationship between the reference numbers and the elements.

What is claimed is:

1. A semiconductor device comprising:
a first replica transistor being a replica of a first transistor included in a control target circuit; and
a first substrate bias control circuit configured to control an impedance of the control target circuit by applying a first substrate bias potential to a substrate of the first transistor, the first substrate bias potential being fed back to the first substrate bias control circuit via the first replica transistor.

2. The semiconductor device according to claim 1, wherein the first replica transistor determines a first potential based on the first substrate bias potential, and
the first substrate bias control circuit outputs the first substrate bias potential based on a comparison between the first potential and a reference potential.

3. The semiconductor device according to claim 2, wherein the first potential is generated by dividing a first preset voltage by a first external resistor and the first replica transistor.

4. The semiconductor device according to claim 2, wherein the first substrate bias control circuit includes:
a first comparator configured to generate a first comparison result by comparing the first potential and the reference potential;
a first up-down counter configured to output a first count value based on the first comparison result; and
a first converter configured to convert the first count value to an analogue value to output as the first substrate bias potential.

5. The semiconductor device according to claim 4, wherein the first comparator generates a plurality of first comparison results by comparing the first potential and the reference potential for each of a plurality of clock cycles,
the first substrate bias control circuit further includes a first majority filter configured to generate a majority value by performing a majority operation to the plurality of first comparison results, and
the first count value is the majority value.

6. The semiconductor device according to claim 4, wherein the first comparator generates a plurality of first comparison results by comparing the first potential and the reference potential for each of a plurality of clock cycles,
the first substrate bias control circuit further includes a first averaging filter configured to generate a first average value by averaging the plurality of first comparison results, and
the first count value is the first average value.

7. The semiconductor device according to claim 1, wherein the control target circuit further includes a second transistor connected to the first transistor via an output terminal, and the first transistor and the second transistor form a complementary metal oxide semiconductor circuit, and
the semiconductor device further comprises:
a second replica transistor being a replica of the second transistor; and
a second substrate bias control circuit configured to control the impedance of the control target circuit by supplying a second substrate bias potential to the second transistor, the second substrate bias potential being fed back to the second substrate bias control circuit via the second replica transistor.

8. The semiconductor device according to claim 7, wherein the first replica transistor determines a first potential based on the first substrate bias potential,
the first substrate bias control circuit outputs the first substrate bias potential based on a comparison between the first potential and a reference potential,
the second replica transistor determines a second potential based on the second substrate bias potential, and
the second substrate bias control circuit outputs the second substrate bias potential based on a comparison between the second potential and the reference potential.

9. The semiconductor device according to claim 8, wherein the second potential is generated by dividing a second preset voltage by a second external resistor and the second replica transistor.

10. The semiconductor device according to claim 9, wherein the first replica transistor is connected to a first voltage supply supplying the first potential to the first transistor,
the second replica transistor is connected to a second voltage supply supplying the second potential to the second transistor,
an end of the first external resistor is connected to the first voltage supply and another end of the first external resistor is connected to the first replica circuit, and
an end of the second external resistor is connected to the second voltage supply and another end of the second external resistor is connected to the second replica circuit.

11. The semiconductor device according to claim 8, wherein the first substrate bias control circuit includes:
a first comparator configured to generate a first comparison result by comparing the first potential and the reference potential;
a first up-down counter configured to output a first count value based on the first comparison result; and
a first converter configured to convert the first count value to an analogue value to output as the first substrate bias potential, and
the second substrate bias control circuit includes:
a second comparator configured to generate a second comparison result by comparing the second potential and the reference potential;
a second up-down counter configured to output a second count value based on the second comparison result; and
a second converter configured to convert the second count value to an analogue value to output as the second substrate bias potential.

12. The semiconductor device according to claim 11, wherein the first comparator generates a plurality of first comparison results by comparing the first potential and the reference potential for each of a plurality of clock cycles,
the first substrate bias control circuit further includes a first majority filter configured to generate a majority value by performing a majority operation to the plurality of first comparison results,
the first count value is the majority value,
the second comparator generates a plurality of second comparison results by comparing the second potential and the reference potential for each of the plurality of clock cycles,
the second substrate bias control circuit further includes a second majority filter configured to generate another majority value by performing a majority operation to the plurality of second comparison results, and
the second count value is the another majority value.

13. The semiconductor device according to claim 11, wherein the first comparator generates a plurality of first comparison results by comparing the first potential and the reference potential for each of a plurality of clock cycles,
the first substrate bias control circuit further includes a first averaging filter configured to generate a first average value by averaging the plurality of first comparison results,
the first count value is the first average value,
the second comparator generates a plurality of second comparison results by comparing the second potential and the reference potential for each of the plurality of clock cycles,
the second substrate bias control circuit further includes a second averaging filter configured to generate a second average value by averaging the plurality of second comparison results, and
the second count value is the second average value.

14. The semiconductor device according to claim 1, further comprising the control target circuit.

15. An impedance control method comprising:
a substrate bias control circuit applying a substrate bias potential to a substrate of a transistor;
feeding back the substrate bias potential to the substrate bias control circuit via a replica transistor being a replica of the transistor; and
the transistor determining an impedance used to control an output impedance of a control target circuit based on the applied substrate bias potential.

16. The impedance control method according to claim 15, further comprising:
the replica transistor determining a first potential based on the substrate bias potential; and
the substrate bias control circuit generating the substrate bias potential based on a comparison between the first potential and a reference potential.

17. The impedance control method according to claim 16, wherein the first potential is generated by dividing a preset voltage by an external resistor and the replica transistor.

18. The impedance control method according to claim 16, wherein the generating includes:
comparing the first potential and the reference potential;
outputting a count value by performing counting up or counting down in response to a result of the comparing; and
converting the outputted count value into an analogue value to output as the substrate bias potential.

19. The impedance control method according to claim 18, wherein the generating further includes:
performing a majority operation to a plurality of results of the comparing; and
generating the count value based on a result of the majority operation.

20. The impedance control method according to claim 18, wherein the generating further includes:
averaging a plurality of results of the comparing; and
generating the count value based on a result of the averaging.
